(19) United States
(12) Patent Application Publication
(10) Pub. No.: US 2026/0172005 A1
(43) Pub. Date: Jun. 18, 2026

(54) BIDIRECTIONAL VARIABLE GAIN PHASE SHIFTER

(71) Applicant: ELECTRONICS AND TELECOMMUNICATIONS RESEARCH INSTITUTE, Daejeon (KR)

(72) Inventors: Seung Hun WANG, Daejeon (KR); Sunwoo Kong, Daejeon (KR); Bong Hyuk Park, Daejeon (KR); Hui Dong Lee, Daejeon (KR)

(21) Appl. No.: 19/405,858

(22) Filed: Dec. 2, 2025

(30) Foreign Application Priority Data
Dec. 12, 2024 (KR) 10-2024-0185273
Aug. 4, 2025 (KR) 10-2025-0106966

(51) Int. Cl. H03H 11/16; H03F 3/45

(52) U.S. Cl. CPC H03H 11/16; H03F 3/45475

(57) ABSTRACT

A bidirectional active-type phase shifter capable of reducing the overall chip size by supporting bidirectional operation is disclosed. The phase shifter includes a first circuit, a second circuit, and a control circuit. The first circuit includes two differential signal terminals and four quadrature signal terminals, and operates as an I/Q generator during a forward operation and as a vector combiner during a reverse operation. The second circuit includes four quadrature signal terminals respectively connected to the quadrature signal terminals of the first circuit and two differential signal terminals, and operates as a vector combiner during the forward operation and as a variable gain differential amplifier during the reverse operation. The control circuit controls the second circuit through four bias current sources, wherein, during the forward operation, currents between the two differential terminals remain identical, and during the reverse operation, currents among the four quadrature terminals remain identical.

### CROSS-REFERENCE TO RELATED APPLICATIONS

The present application claims the benefit of priority under 35 U.S.C. § 119 based on Korean Patent Application No. 10-2024-0185273 filed on Dec. 12, 2024, and Korean Patent Application No. 10-2025-0106966 filed on Aug. 4, 2025, with the Korean Intellectual Property Office, the entire content of which is incorporated herein by reference.

### BACKGROUND

### 1. Technical Field

The present disclosure relates to a bidirectional variable gain phase shifter, and more particularly, to a bidirectional variable gain phase shifter applicable to a wireless radio frequency integrated circuit or the like for a beamforming system.

### 2. Description of the Related Art

A phase shifter may be classified into a passive type and an active type. There exists a trade-off between gain (or loss) and DC power consumption between the passive-type phase shifter and the active-type phase shifter. The passive-type phase shifter has zero DC power consumption, but in terms of loss characteristics, the active-type phase shifter exhibits better performance. In addition, the active-type phase shifter has an advantage of providing bit-independent gain.

As the resolution increases, the passive-type phase shifter experiences greater loss, whereas the active-type phase shifter suffers less from such an issue. In terms of input P1dB characteristics, the passive-type phase shifter is clearly superior. Regarding the gain control function, when the configuration is implemented using four sub amplifiers simultaneously, it is possible to obtain the advantages of the active-type phase shifter and, without generating additional insertion loss, control both phase and gain at a very high resolution within a single block. The control can be performed without an additional block, while the passive-type phase shifter requires an attenuator to control gain, which results in larger loss. In terms of size, the passive-type and active-type phase shifters have similar dimensions for about 4-bit phase control, but as the resolution increases, the active-type phase shifter becomes smaller than the passive-type phase shifter. Accordingly, except for the P1dB characteristic in high-resolution control, the active-type phase shifter is superior to the passive-type phase shifter overall.

However, since the active-type phase shifter is unidirectional, two active-type phase shifters are required respectively for transmission (Tx) and reception (Rx). In contrast, the passive-type phase shifter has a bidirectional characteristic and thus only one can be used in a TRx chain. Therefore, even though the active-type phase shifter is smaller, the need for two of them in the TRx chain results in a larger overall size compared to the passive-type phase shifter. Accordingly, a phase shifter is required that can reduce the overall chip size required for the entire system by realizing the active-type phase shifter as a bidirectional one while maintaining the low loss and high-resolution independent gain and phase control characteristics of the conventional vector-sum-type variable gain phase shifter.

### SUMMARY

An objective of the present disclosure for solving the above-described problems is to provide a phase shifter capable of reducing a chip size required for an entire system by realizing an active-type phase shifter as a bidirectional one while maintaining low loss and high-resolution independent gain and phase control.

A bidirectional variable gain phase shifter according to exemplary embodiments of the present disclosure comprises a first circuit including a pair of first differential signal terminals that receive or output differential signals and four first quadrature signal terminals that receive or output quadrature signals, the first circuit being configured to operate as an I/Q generator in a first direction and to operate as a vector combiner in a second direction opposite to the first direction; a second circuit including four second quadrature signal terminals respectively connected to the four first quadrature signal terminals and a pair of second differential signal terminals, the second circuit being configured to operate as a vector combiner in the first direction and to operate as a variable gain differential amplifier in the second direction; and a control circuit configured to control the second circuit through first, second, third, and fourth bias current sources, wherein the first direction is from the first circuit toward the second circuit, and the second direction is from the second circuit toward the first circuit, wherein, during a forward operation, a first DC bias currents flowing through the two second differential signal terminals are controlled to be substantially equal, and during a reverse operation, a second DC bias currents flowing through the four second quadrature signal terminals are controlled to be substantially equal.

Hereinafter, the first direction and the second direction may be referred to as a forward direction and a reverse direction, respectively.

The second circuit may comprise a plurality of transistors, and the four second quadrature signal terminals may correspond to output terminals of the plurality of transistors.

During the forward operation, a sum of DC bias currents flowing through the second differential signal terminals during the forward operation is maintained to be substantially equal to a sum of DC bias currents flowing through the second quadrature signal terminals during the reverse operation.

The second circuit may be configured such that a gain of each path varies according to phase information of signals input or output through the four second quadrature signal terminals.

The second circuit may comprise a first differential amplification circuit group including the four second quadrature signal terminals and the two second differential signal terminals; and a second differential amplification circuit group sharing the second quadrature signal terminals and the second differential signal terminals of the first differential amplification circuit group.

The first differential amplification circuit group and the second differential amplification circuit group may output first and second differential signals generated based on signals input through the first quadrature signal terminals through mutually opposite second differential signal terminals.

The control circuit may provide bias currents respectively to the first differential amplification circuit group and the second differential amplification circuit group and may be configured to maintain a total sum of the bias currents constant.

The first differential amplification circuit group may be controlled through the first and second bias current sources, and the second differential amplification circuit group may be controlled through the third and fourth bias current sources.

The control circuit may include a digital-to-analog converter (DAC), and the first, second, third, and fourth bias current sources may be set according to output values of the DAC.

During the forward operation, the first quadrature signal terminals may respectively output a first phase signal (I+), a second phase signal (I−), a third phase signal (Q+), and a fourth phase signal (Q−), and during the reverse operation, the second quadrature signal terminals may respectively output a fifth phase signal (I′(+)), a sixth phase signal (I′(−)), a seventh phase signal (Q′(+)), and an eighth phase signal (Q′(−)), wherein the phase-combined signals satisfy I′(+)=I++Q+, I′(−)=I−+Q−, Q′(+)=I−+Q+, and Q′(−)=I++Q−.

The bidirectional variable gain phase shifter may further comprise a first transmission line transformer connected to the first differential signal terminals.

The bidirectional variable gain phase shifter may further comprise a second transmission line transformer connected to the second differential signal terminals.

According to the bidirectional variable gain phase shifter of the exemplary embodiments of the present disclosure, even during reverse operation, stable vector synthesis is achievable since the currents flowing through the four second quadrature signal terminals remain identical to each other.

In addition, by sharing a digital-to-analog converter (DAC) and a passive network in both forward and reverse operations, circuit complexity can be significantly reduced, and the chip area can be minimized.

Furthermore, during the reverse operation, since vector synthesis occurs in a first circuit (I/Q generator) that operates as a vector combiner after passing through a second circuit operating as a variable gain amplifier without passing through an I/Q generator having high loss, advantages can be obtained in terms of noise figure.

### BRIEF DESCRIPTION OF THE DRAWINGS

In order that the disclosure may be well understood, there will now be described various forms thereof, given by way of example, reference being made to the accompanying drawings, in which:

FIG. 1 is a schematic diagram of a bidirectional variable gain phase shifter according to exemplary embodiments of the present disclosure.

FIGS. 2 and 3 are conceptual diagrams illustrating forward and reverse operations, respectively, of the bidirectional variable gain phase shifter shown in FIG. 1.

FIGS. 4 and 5 are conceptual diagrams illustrating a first circuit shown in FIG. 1 operating as an I/Q generator during a forward operation and as a vector combiner during a reverse operation, respectively.

FIG. 6 is a schematic diagram of a bidirectional variable gain phase shifter according to exemplary embodiments of the present disclosure.

FIG. 7 is a circuit diagram illustrating exemplary embodiments of a second circuit during a forward operation.

FIG. 8 is a circuit diagram illustrating a comparative example of a second circuit during a reverse operation.

FIG. 9 is a circuit diagram illustrating exemplary embodiments of a second circuit during a reverse operation.

FIGS. 10 and 11 are diagrams for explaining the operation of the circuit diagram shown in FIG. 9.

The drawings described herein are for illustration purposes only and are not intended to limit the scope of the present disclosure in any way.

### DETAILED DESCRIPTION

For a clearer understanding of the features and advantages of the present disclosure, exemplary embodiments of the present disclosure will be described in detail with reference to the accompanied drawings. However, it should be understood that the present disclosure may be not be limited to particular embodiments disclosed herein but includes all modifications, equivalents, and alternatives falling within the spirit and scope of the present disclosure. In the drawings, similar or corresponding components may be designated by the same or similar reference numerals.

The terminologies including ordinals such as “first” and “second” or another identifiers such as “A” and “B” may be used to discriminate a component from the other ones but may not be intended to be limiting to a specific component. For example, a second component may be referred to as a first component and, similarly, a first component may also be referred to as a second component without departing from the scope of the present disclosure. As used herein, the term “and/or” may include a presence of one or more of the associated listed items and any and all combinations of the listed items.

When a component is referred to as being “connected” or “coupled” to another component, the component may be directly connected or coupled logically or physically to the other component or indirectly through an object therebetween. Contrarily, when a component is referred to as being “directly connected” or “directly coupled” to another component, it is to be understood that there is no intervening object between the components. Other words used to describe the relationship between elements should be interpreted in a similar fashion.

The terminologies may be used herein for the purpose of describing particular exemplary embodiments only and may not be intended to limit the present disclosure. The singular forms include plural referents as well unless the context clearly dictates otherwise. Also, the expressions “comprises” or “includes” may be used to refer a presence of a combination of stated features, numbers, processing steps, operations, elements, or components, but may not be intended to preclude a presence or addition of another feature, number, processing step, operation, element, or component.

Unless defined otherwise, all terms used herein, including technical or scientific terms, have the same meaning as commonly understood by those of ordinary skill in the art to which the present disclosure pertains. Terms such as those defined in a commonly used dictionary should be interpreted as having meanings consistent with their meanings in the context of related literatures and will not be interpreted as having ideal or excessively formal meanings unless explicitly defined in the present application.

Hereinafter, preferred exemplary embodiments according to the present disclosure will be described in detail with reference to the accompanying drawings.

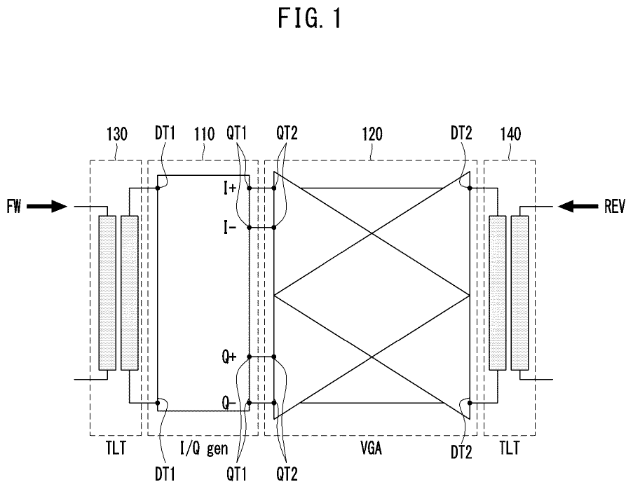

FIG. 1 is a schematic diagram of a bidirectional variable gain phase shifter according to exemplary embodiments of the present disclosure.

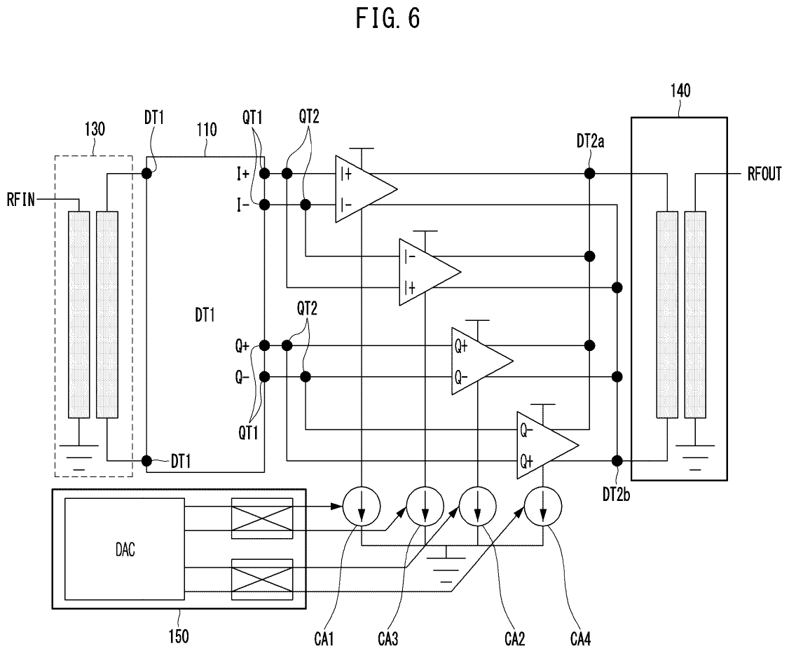

As shown in FIG. 1, a bidirectional variable gain phase shifter according to exemplary embodiments of the present disclosure includes a first circuit 110, a second circuit 120, and a control circuit (150 in FIG. 6). The bidirectional variable gain phase shifter may further include at least one of a first transmission line transformer 130 and a second transmission line transformer 140.

The first circuit 110 includes two first differential signal terminals DT1 and first quadrature signal terminals QT1. The two first differential signal terminals DT1 receive or output differential signals. The four first quadrature signal terminals QT1 receive or output quadrature signals. The first circuit 110 is configured to operate as an I/Q generator during a forward operation and to operate as a vector combiner during a reverse operation.

During the forward operation, the first circuit 110 receives differential signals through the first differential signal terminals DT1 from the first transmission line transformer 130 and outputs a first phase signal I+, a second phase signal I−, a third phase signal Q+, and a fourth phase signal Q− through the first quadrature signal terminals QT1. The first phase signal I+ and the second phase signal I− have a phase difference of 180 degrees, the third phase signal Q+ and the fourth phase signal Q− have a phase difference of 180 degrees, and the first phase signal I+ and the third phase signal Q+ have a phase difference of 90 degrees.

During the reverse operation, the first circuit 110 receives four phase signals from the second circuit 120 through the first quadrature signal terminals QT1. In this case, among the four phase signals, the phase signals input to the terminals marked I+ and I− have a phase difference of 180 degrees, the phase signals input to the terminals marked Q+ and Q− have a phase difference of 180 degrees, and the terminals marked I+ and Q+ have the same phase.

The first circuit 110 may be implemented with a hybrid coupler, an RC poly phase filter, an RC-RL poly phase filter, an RL poly phase filter, a quadrature all-pass filter, or the like.

The second circuit 120 includes four second quadrature signal terminals QT2 and two second differential signal terminals DT2. The second quadrature signal terminals QT2 are connected respectively to the first quadrature signal terminals QT1. The second circuit 120 is configured to operate as a vector combiner during the forward operation and to operate as a variable gain differential amplifier during the reverse operation. In one exemplary embodiment, the second circuit 120 includes a plurality of transistors, and the four second quadrature signal terminals QT2 may correspond to output terminals of the transistors. The second circuit 120 may be configured such that the gain of each path varies according to phase information of a signal input or output through the four second quadrature signal terminals QT2. The configuration of the second circuit 120 will be described in detail later.

The control circuit (150 in FIG. 6) controls the second circuit 120 through first, second, third, and fourth bias current sources.

In the bidirectional variable gain phase shifter according to exemplary embodiments of the present disclosure, during the forward operation, currents flowing through the two second differential signal terminals DT2 remain identical to each other, and during the reverse operation, currents flowing through the four second quadrature signal terminals QT2 remain identical to each other.

The first transmission line transformer 130 is connected to the first differential signal terminals DT1, and the second transmission line transformer 140 is connected to the second differential signal terminals DT2. The first transmission line transformer 130 and the second transmission line transformer 140 match impedance or perform power distribution through differences in transmission line phase and length. The first transmission line transformer 130 and the second transmission line transformer 140 may be formed using a ferrite core (or bead) with multiple windings or may be implemented through a coaxial line. When the first transmission line transformer 130 and the second transmission line transformer 140 are formed using a ferrite core (or bead) with multiple windings, they are mainly used in relatively low-power circuits and low-frequency bands, but allow easy impedance transformation with various values and can be manufactured in small sizes. When the first transmission line transformer 130 and the second transmission line transformer 140 are implemented through a coaxial line, they operate only with a fixed impedance ratio but have excellent reproducibility of operation and can be used in high-power circuits and relatively high-frequency regions.

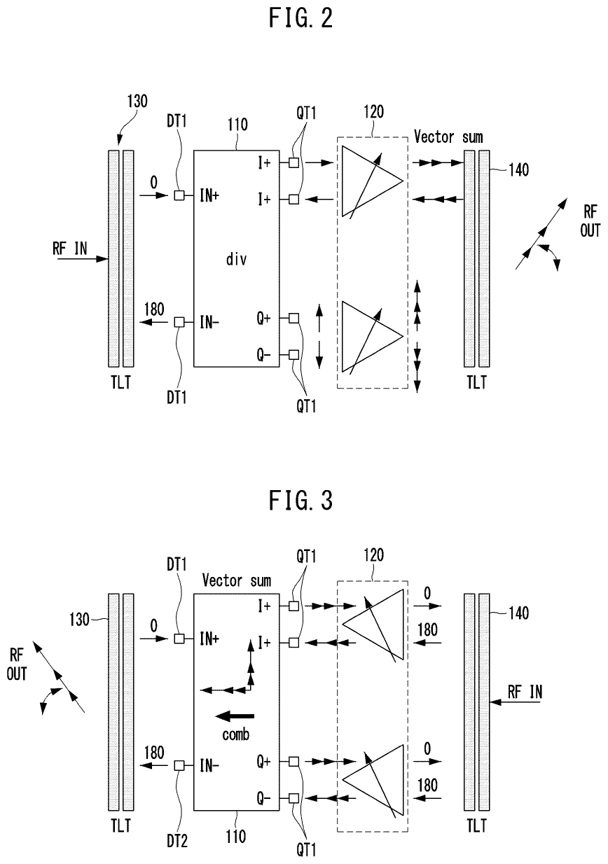

FIGS. 2 and 3 are conceptual diagrams illustrating forward and reverse operations, respectively, of the bidirectional variable gain phase shifter shown in FIG. 1.

As shown in FIG. 2, during the forward operation, an RF signal RF IN is converted into a differential signal through the first transmission line transformer 130 operating as a balun. The differential signal is input through the first differential signal terminals DT1 and converted by the first circuit 110 operating as an I/Q generator into a first phase signal I+, a second phase signal I−, a third phase signal Q+, and a fourth phase signal Q−, which are output respectively through the first quadrature signal terminals QT1.

The output signals are applied to the second circuit 120 operating as a vector combiner, in which the magnitudes of the first phase signal I+, the second phase signal I−, the third phase signal Q+, and the fourth phase signal Q− are individually controlled and combined, and the combined signal is output through the second transmission line transformer 140 as an RF signal RF OUT whose magnitude and phase are adjusted.

As shown in FIG. 3, during the reverse operation, the RF signal RF IN is converted into a differential signal through the second transmission line transformer 140 operating as a balun. The converted differential signal passes through the second differential signal terminals DT2 and is separated by the second circuit 120 operating as a variable gain differential amplifier into a fifth phase signal I′(+), a sixth phase signal I′(−), a seventh phase signal Q′(+), and an eighth phase signal Q′(−).

These phase signals are delivered to the first circuit 110 operating as a vector combiner, in which respective phase components are combined and vector synthesis is performed to form a differential RF signal. The combined differential signal is output through the first differential signal terminals DT1 and converted into a single RF signal RF OUT through the first transmission line transformer 130.

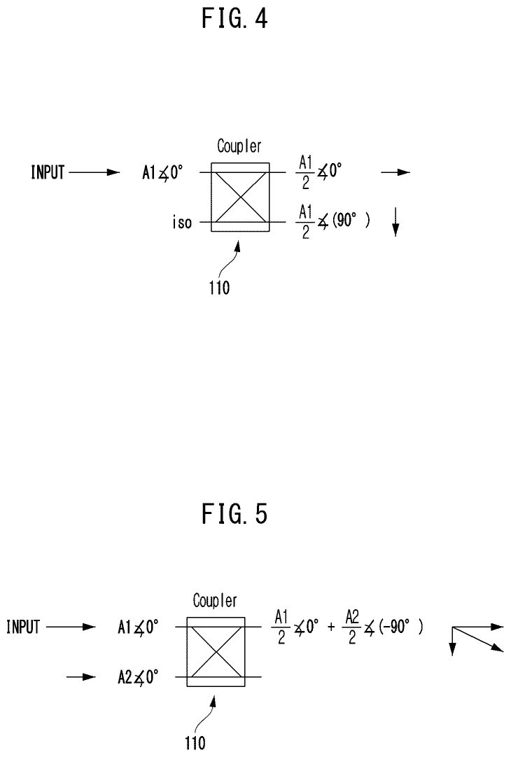

FIGS. 4 and 5 are conceptual diagrams illustrating the first circuit shown in FIG. 1 operating as an I/Q generator during the forward operation and as a vector combiner during the reverse operation, respectively.

As shown in FIGS. 1 and 4, the first circuit 110 according to exemplary embodiments operates as an I/Q generator during the forward operation. More specifically, an RF signal A1∠0° having a single phase component input from an input terminal is separated through the first circuit 110 into two signals having the same magnitude but a 90-degree phase difference. For example, as shown in FIG. 4, the input signal A1∠0° is separated into an I-axis signal A1/2∠0° and a Q-axis signal A1/2∠−90°, which correspond respectively to orthogonal components in a vector space.

The separated I/Q components are transferred to the second circuit 120 at the subsequent stage, where independent amplification or phase control can be performed for each component, and ultimately, a phase-shifted RF signal can be synthesized and output.

In contrast, referring to FIGS. 1 and 5, the first circuit 110 performs a function of a vector combiner during the reverse operation. In this case, two I/Q phase components A1∠0° and A2∠0° delivered from the second circuit 120 or a preceding circuit are input to the first circuit 110, which operates as a vector combiner. As shown in FIG. 5, the vector combiner combines the two input signals in a predetermined ratio to synthesize a single RF output signal.

Specifically, the signal output from the vector combiner has a form of A1/2∠0°+A2/2∠−90°, which represents the result of vector synthesis of orthogonal components. Since the two phase components are physically added vectorially inside the combiner, the phase and amplitude of the final RF output signal can be adjusted.

Consequently, the first circuit 110 can operate as an I/Q generator during the forward operation and as a vector combiner during the reverse operation within the same hardware structure, so that the bidirectional phase control circuit can be integrated into a single common structure. This enables reduction of the chip area while maintaining circuit functionality and is particularly suitable for a phased array antenna system or an RF transceiver module requiring bidirectional phase adjustment for both transmission and reception.

In addition, by implementing the I/Q generator and the vector combiner using a single combining structure instead of separate blocks, the complexity and power consumption of the passive network can be reduced, and insertion loss in the signal path can be minimized. Furthermore, the circuit configuration operates in conjunction with a digital control-based DAC and a quadrant selector to enable more precise variable gain control and phase vector synthesis.

Accordingly, the bidirectional variable gain phase shifter according to the present disclosure provides excellent technical effects in terms of circuit integration, phase accuracy, system miniaturization, and power efficiency.

FIG. 6 is a schematic diagram of a bidirectional variable gain phase shifter according to exemplary embodiments of the present disclosure.

As shown in FIG. 6, the bidirectional variable gain phase shifter according to exemplary embodiments of the present disclosure is configured to precisely control the phase and magnitude of a radio frequency (RF) signal while allowing bidirectional operation. In particular, the exemplary embodiments realize forward and reverse signal paths within a single circuit, thereby enabling reuse of a digital-to-analog converter (DAC) and passive network, and consequently achieving an efficient circuit configuration without duplication of components. Accordingly, the bidirectional variable gain phase shifter is designed to effectively achieve improved system integration and chip size reduction.

During the forward operation, an RF input signal RF IN is introduced through a first transmission line transformer (TLT) 130 that functions as a balun, converting a single RF input into a differential RF signal. The converted differential signal is delivered to a first circuit 110 operating as an I/Q generator. The first circuit 110 generates four signal components having a 90-degree phase difference with respect to the input signal, namely, a first phase signal I+, a second phase signal I−, a third phase signal Q+, and a fourth phase signal Q−. For example, the first phase signal I+ may have a phase of 0°, the second phase signal I− may have a phase of 180°, the third phase signal Q+ may have a phase of 90°, and the fourth phase signal Q− may have a phase of 270°. These signals are delivered to a subsequent circuit, namely a second circuit 120.

The second circuit 120 includes a plurality of variable gain amplifiers capable of independently amplifying and controlling the four phase components. Each amplifier receives a corresponding phase component (I+, I−, Q+, Q−) as an input, and its gain is individually controlled according to bias currents supplied from a DAC (digital-to-analog converter) and a quadrant selection circuit. This configuration realizes the vector synthesis operation essential for the phase shifter, thereby allowing generation of a synthesized RF signal having a desired phase and amplitude.

Meanwhile, the total bias current amount is configured to remain constant (Total current=K), thereby achieving uniform power consumption and improved linearity. Such a current synthesis method enables high-precision phase control and minimizes phase error. In addition, since the total bias current amount is maintained constant (Total current=K), the sum of currents flowing through the second differential signal terminals DT2 during the forward operation can be identical to the sum of currents flowing through the second quadrature signal terminals QT2 during the reverse operation.

For example, the second circuit 120 may include a first differential amplification circuit group 121 and a second differential amplification circuit group 122. The first differential amplification circuit group 121 may include the four second quadrature signal terminals QT2 and the two second differential signal terminals DT2. The second differential amplification circuit group 122 may share the second quadrature signal terminals QT2 and the second differential signal terminals DT2 of the first differential amplification circuit group 121.

In this case, the first differential amplification circuit group 121 and the second differential amplification circuit group 122 may output first and second differential signals having opposite phases through mutually opposite second differential signal terminals DT2 based on first and second differential signals generated from signals input through the first quadrature signal terminals QT1.

More specifically, the first differential amplification circuit group 121 receives first to fourth phase signals (I+, I−, Q+, Q−) through the first quadrature signal terminals QT1, and based on these signals, outputs first and second differential signals having opposite phases through upper and lower signal terminals (DT2a, DT2b) among the second differential signal terminals DT2, as illustrated in the figure.

In contrast, the second differential amplification circuit group 122 also receives the first to fourth phase signals (I+, I−, Q+, Q−) through the first quadrature signal terminals QT1, but outputs the opposite-phase first and second differential signals through the second differential signal terminals DT2 located at lower and upper positions (DT2b, DT2a), respectively.

By connecting the outputs of the first differential amplification circuit group and the second differential amplification circuit group to opposite second differential signal terminals DT2a and DT2b, the currents flowing through the second quadrature signal terminals QT2 can remain identical even during the reverse operation.

The synthesized RF signal is reconverted from a differential signal into a single signal through an output transmission line transformer (output TLT) and delivered as an RF output RF OUT.

Meanwhile, the phase and gain of the second circuit 120 may be controlled by a control circuit 150. The control circuit 150 provides bias currents to the first differential amplification circuit group 121 and the second differential amplification circuit group 122 and may be configured to maintain the total sum of the bias currents constant.

For example, the first differential amplification circuit group 121 may be controlled by a first bias current source CA1 and a second bias current source CA2, and the second differential amplification circuit group 122 may be controlled by a third bias current source CA3 and a fourth bias current source CA4.

To control the amount of current flowing through the first to fourth bias current sources CA1, CA2, CA3, and CA4, the control circuit 150 may include a digital-to-analog converter (DAC). The DAC converts digital signals input from the outside into analog signals to control the amount of current flowing through the first to fourth bias current sources CA1, CA2, CA3, and CA4.

As a result, the same circuit can receive an RF input through the second transmission line transformer 140 during the reverse operation, separate I/Q components in the same manner, perform amplification control and synthesis, and output the result through the first transmission line transformer 130. Such a bidirectional operation characteristic means that a single circuit block can accommodate both forward and reverse signal paths, thereby allowing reuse of components without additional circuit blocks.

Moreover, by sharing the DAC and passive network in both forward and reverse operations, the phase shifter can significantly reduce circuit complexity and minimize chip area. Therefore, the present exemplary embodiment provides superior circuit efficiency and integration compared to conventional unidirectional phase shifters and can be very effectively applied to RF communication systems or phased array antennas.

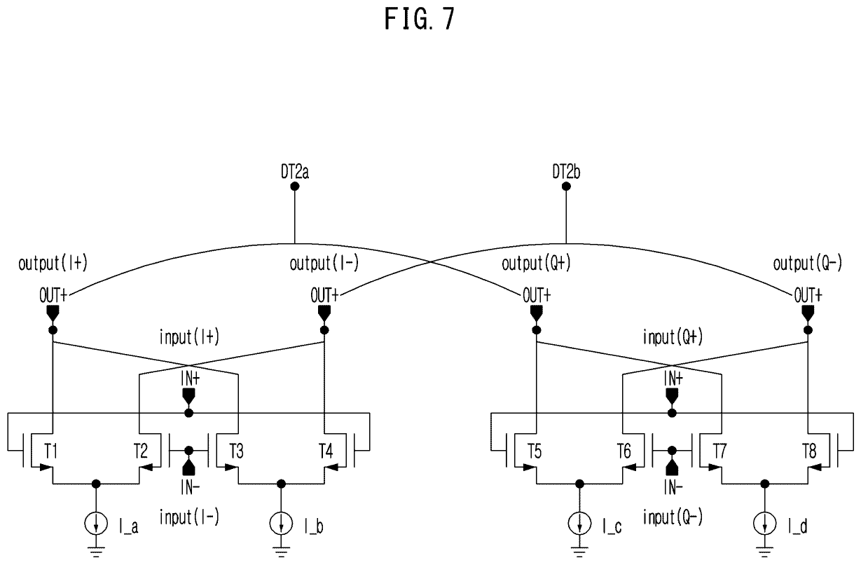

FIG. 7 is a circuit diagram illustrating exemplary embodiments of the second circuit during a forward operation.

As shown in FIG. 7, for example, during the forward operation, the second circuit operating as a vector combiner may include, for example, a first transistor T1, a second transistor T2, a third transistor T3, a fourth transistor T4, a fifth transistor T5, a sixth transistor T6, a seventh transistor T7, and an eighth transistor T8.

For example, a source terminal of the first transistor T1 and a source terminal of the second transistor T2 are connected to each other and may be connected to a first bias current source Ia. In addition, a source terminal of the third transistor T3 and a source terminal of the fourth transistor T4 are connected to each other and may be connected to a second bias current source Ib. In addition, a source terminal of the fifth transistor T5 and a source terminal of the sixth transistor T6 are connected to each other and may be connected to a third bias current source Ic. In addition, a source terminal of the seventh transistor T7 and a source terminal of the eighth transistor T8 are connected to each other and may be connected to a fourth bias current source Id.

A gate terminal of the first transistor T1 and a gate terminal of the fourth transistor T4 are connected to each other and may be connected to a signal terminal that outputs a first phase signal I+ among first quadrature signal terminals of the first circuit operating as an I/Q generator. In addition, a gate terminal of the second transistor T2 and a gate terminal of the third transistor T3 are connected to each other and may be connected to a signal terminal that outputs a second phase signal I− among the first quadrature signal terminals of the first circuit operating as the I/Q generator. In addition, a gate terminal of the fifth transistor T5 and a gate terminal of the eighth transistor T8 are connected to each other and may be connected to a signal terminal that outputs a third phase signal Q+ among the first quadrature signal terminals of the first circuit operating as the I/Q generator. In addition, a gate terminal of the sixth transistor T6 and a gate terminal of the seventh transistor T7 are connected to each other and may be connected to a signal terminal that outputs a fourth phase signal Q− among the first quadrature signal terminals of the first circuit operating as the I/Q generator.

A drain terminal of the first transistor T1 and a drain terminal of the third transistor T3 are connected to each other and may be connected to an upper second differential signal terminal DT2a shown in FIG. 6. In addition, a drain terminal of the second transistor T2 and a drain terminal of the fourth transistor T4 are connected to each other and may be connected to a lower second differential signal terminal DT2b shown in FIG. 6. In addition, a drain terminal of the fifth transistor T5 and a drain terminal of the seventh transistor T7 are connected to each other and may be connected to the upper second differential signal terminal DT2a shown in FIG. 6. In addition, a drain terminal of the sixth transistor T6 and a drain terminal of the eighth transistor T4 are connected to each other and may be connected to the lower second differential signal terminal DT2b shown in FIG. 6.

In this connection, although a total sum of currents flowing through the first bias current source Ia, the second bias current source Ib, the third bias current source Ic, and the fourth bias current source Id is fixed (Ia+Ib+Ic+Id=K), a vector sum is generated by adjusting individual magnitudes of the bias current sources.

By way of several extreme examples, when Ia=Ib=Ic=Id=K/4, magnitudes of the second phase signal I− having a phase difference of 180 degrees with the first phase signal I+ are identical so that a vector sum along the I axis is zero, and magnitudes of the fourth phase signal Q− having a phase difference of 180 degrees with the third phase signal Q+ are identical so that a vector sum along the Q axis is zero, whereby a total output becomes zero.

In addition, when Ia=K and Ib=Ic=Id=0, an output signal having the same phase as the first phase signal I+ is generated, and when Ib=K and Ia=Ic=Id=0, an output signal having the same phase as the second phase signal I− is generated.

Similarly, when Ic=K and Ia=lb=Id=0, an output signal having the same phase as the third phase signal Q+ is generated, and when Id=K and Ia=lb=Ic=0, an output signal having the same phase as the fourth phase signal Q− is generated.

As shown in FIG. 7, in the variable gain phase shifter operating in the forward direction, regardless of which one of the first to fourth phase signals I+, I−, Q+, and Q− is input, transistors connected to two output signal terminals, namely the second differential signal terminals DT2a and DT2b, are always turned on so that constant DC currents flow through the second differential signal terminals DT2a and DT2b, whereby normal operation is achievable.

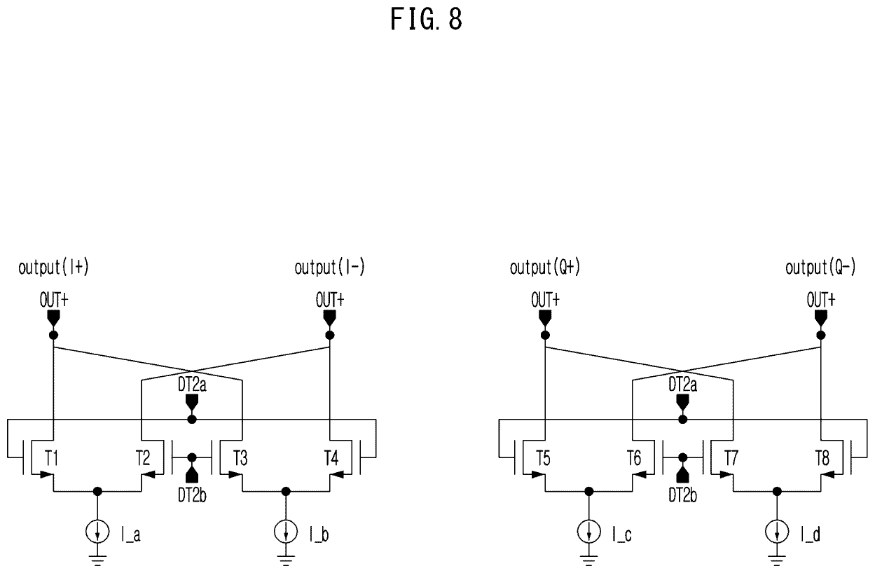

FIG. 8 is a circuit diagram illustrating a comparative example of the second circuit during a reverse operation.

As shown in FIG. 8, for example, during the reverse operation, the second circuit according to the comparative example operating as a variable gain differential amplifier may include, for example, a first transistor T1, a second transistor T2, a third transistor T3, a fourth transistor T4, a fifth transistor T5, a sixth transistor T6, a seventh transistor T7, and an eighth transistor T8.

For example, a source terminal of the first transistor T1 and a source terminal of the second transistor T2 are connected to each other and may be connected to a first bias current source Ia. In addition, a source terminal of the third transistor T3 and a source terminal of the fourth transistor T4 are connected to each other and may be connected to a second bias current source Ib. In addition, a source terminal of the fifth transistor T5 and a source terminal of the sixth transistor T6 are connected to each other and may be connected to a third bias current source Ic. In addition, a source terminal of the seventh transistor T7 and a source terminal of the eighth transistor T8 are connected to each other and may be connected to a fourth bias current source Id.

A gate terminal of the first transistor T1 and a gate terminal of the fourth transistor T4 are connected to each other and may be connected to the upper second differential signal terminal DT2a shown in FIG. 6. In addition, a gate terminal of the second transistor T2 and a gate terminal of the third transistor T3 are connected to each other and may be connected to the lower second differential signal terminal DT2b shown in FIG. 6. In addition, a gate terminal of the fifth transistor T5 and a gate terminal of the eighth transistor T8 are connected to each other and may be connected to the upper second differential signal terminal DT2a shown in FIG. 6. In addition, a gate terminal of the sixth transistor T6 and a gate terminal of the seventh transistor T7 are connected to each other and may be connected to the lower second differential signal terminal DT2b shown in FIG. 6.

A drain terminal of the first transistor T1 and a drain terminal of the third transistor T3 are connected to each other and may be connected to a signal terminal corresponding to the third phase signal Q+ among the first quadrature signal terminals of the first circuit 110 shown in FIG. 6. In addition, a drain terminal of the second transistor T2 and a drain terminal of the fourth transistor T4 are connected to each other and may be connected to a signal terminal corresponding to the fourth phase signal Q− among the first quadrature signal terminals of the first circuit 110 shown in FIG. 6. In addition, a drain terminal of the fifth transistor T5 and a drain terminal of the seventh transistor T7 are connected to each other and may be connected to a signal terminal corresponding to the first phase signal I+ among the first quadrature signal terminals of the first circuit 110 shown in FIG. 6. In addition, a drain terminal of the sixth transistor T6 and a drain terminal of the eighth transistor T4 are connected to each other and may be connected to a signal terminal corresponding to the second phase signal I− among the first quadrature signal terminals of the first circuit 110 shown in FIG. 6.

In this connection, although a total sum of currents flowing through the first bias current source Ia, the second bias current source Ib, the third bias current source Ic, and the fourth bias current source Id is fixed (Ia+lb+Ic+Id=K), variable gain is controlled by adjusting individual magnitudes of the bias current sources.

However, in this case, currents at first to fourth quadrature signal terminals corresponding to output nodes, namely the first to fourth phase signals I+, I−, Q+, and Q−, vary over time, thereby changing impedance so that normal operation as a variable gain phase shifter cannot be achieved.

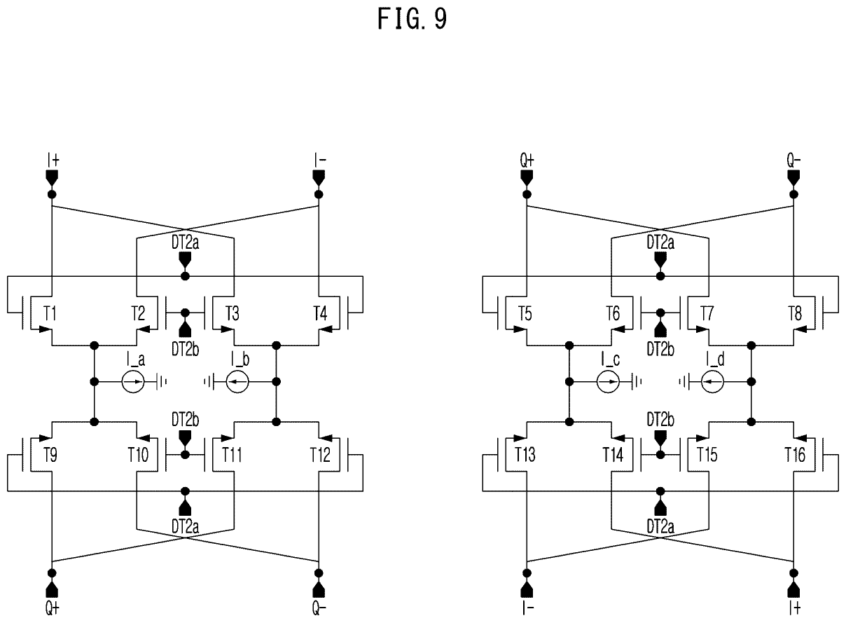

FIG. 9 is a circuit diagram illustrating exemplary embodiments of the second circuit during a reverse operation.

As shown in FIG. 9, for example, the second circuit operating as a variable gain differential amplifier may include, for example, a first transistor T1, a second transistor T2, a third transistor T3, a fourth transistor T4, a fifth transistor T5, a sixth transistor T6, a seventh transistor T7, an eighth transistor T8, a ninth transistor T9, a tenth transistor T10, an eleventh transistor T11, a twelfth transistor T12, a thirteenth transistor T13, a fourteenth transistor T14, a fifteenth transistor T15, and a sixteenth transistor T16.

For example, a source terminal of the first transistor T1 and a source terminal of the second transistor T2 are connected to each other and may be connected to a first bias current source Ia. In addition, a source terminal of the third transistor T3 and a source terminal of the fourth transistor T4 are connected to each other and may be connected to a second bias current source Ib. In addition, a source terminal of the fifth transistor T5 and a source terminal of the sixth transistor T6 are connected to each other and may be connected to a third bias current source Ic. In addition, a source terminal of the seventh transistor T7 and a source terminal of the eighth transistor T8 are connected to each other and may be connected to a fourth bias current source Id. In addition, a source terminal of the ninth transistor T9 and a source terminal of the tenth transistor T10 are connected to each other and may be connected to the first bias current source Ia. In addition, a source terminal of the eleventh transistor T11 and a source terminal of the twelfth transistor T12 are connected to each other and may be connected to the second bias current source Ib. In addition, a source terminal of the thirteenth transistor T13 and a source terminal of the fourteenth transistor T14 are connected to each other and may be connected to the third bias current source Ic. In addition, a source terminal of the fifteenth transistor T15 and a source terminal of the sixteenth transistor T16 are connected to each other and may be connected to the fourth bias current source Id.

A gate terminal of the first transistor T1 and a gate terminal of the fourth transistor T4 are connected to each other and may be connected to an upper second differential signal terminal DT2a shown in FIG. 6. In addition, a gate terminal of the second transistor T2 and a gate terminal of the third transistor T3 are connected to each other and may be connected to a lower second differential signal terminal DT2b shown in FIG. 6. In addition, a gate terminal of the fifth transistor T5 and a gate terminal of the eighth transistor T8 are connected to each other and may be connected to the upper second differential signal terminal DT2a shown in FIG. 6. In addition, a gate terminal of the sixth transistor T6 and a gate terminal of the seventh transistor T7 are connected to each other and may be connected to the lower second differential signal terminal DT2b shown in FIG. 6. In addition, a gate terminal of the ninth transistor T9 and a gate terminal of the twelfth transistor T12 are connected to each other and may be connected to the upper second differential signal terminal DT2a shown in FIG. 6. In addition, a gate terminal of the tenth transistor T10 and a gate terminal of the eleventh transistor T11 are connected to each other and may be connected to the lower second differential signal terminal DT2b shown in FIG. 6. In addition, a gate terminal of the thirteenth transistor T13 and a gate terminal of the sixteenth transistor T16 are connected to each other and may be connected to the upper second differential signal terminal DT2a shown in FIG. 6. In addition, a gate terminal of the fourteenth transistor T14 and a gate terminal of the fifteenth transistor T15 are connected to each other and may be connected to the lower second differential signal terminal DT2b shown in FIG. 6.

A drain terminal of the first transistor T1 and a drain terminal of the third transistor T3 are connected to each other and may be connected to a signal terminal that outputs a first phase signal I+ among first quadrature signal terminals of the first circuit. In addition, a drain terminal of the second transistor T2 and a drain terminal of the fourth transistor T4 are connected to each other and may be connected to a signal terminal that outputs a second phase signal I− among the first quadrature signal terminals of the first circuit. In addition, a drain terminal of the fifth transistor T5 and a drain terminal of the seventh transistor T7 are connected to each other and may be connected to a signal terminal that outputs a third phase signal Q+ among the first quadrature signal terminals of the first circuit. In addition, a drain terminal of the sixth transistor T6 and a drain terminal of the eighth transistor T4 are connected to each other and may be connected to a signal terminal that outputs a fourth phase signal Q− among the first quadrature signal terminals of the first circuit. In addition, a drain terminal of the ninth transistor T9 and a drain terminal of the eleventh transistor T11 are connected to each other and may be connected to a signal terminal that outputs a third phase signal Q+ among the first quadrature signal terminals of the first circuit. In addition, a drain terminal of the tenth transistor T10 and a drain terminal of the twelfth transistor T12 are connected to each other and may be connected to a signal terminal that outputs a fourth phase signal Q− among the first quadrature signal terminals of the first circuit. In addition, a drain terminal of the thirteenth transistor T13 and a drain terminal of the fifteenth transistor T15 are connected to each other and may be connected to a signal terminal that outputs a second phase signal I− among the first quadrature signal terminals of the first circuit. In addition, a drain terminal of the fourteenth transistor T14 and a drain terminal of the sixteenth transistor T16 are connected to each other and may be connected to a signal terminal that outputs a first phase signal I+ among the first quadrature signal terminals of the first circuit.

In a case having such a connection, unlike FIG. 8 described above, regardless of which one of the two differential signals input from the second transmission line transformer is applied, transistors connected to the four second quadrature signal terminals remain turned on, thereby causing identical direct currents to flow through the second quadrature signal terminals, and thus a stable variable gain phase shifter for reverse operation can be realized.

Meanwhile, the second circuit for the reverse operation shown in FIG. 9 and the second circuit for the forward operation shown in FIG. 7 may be configured as separate circuits respectively and used for each of the forward and reverse operations, or switches may be configured in the circuit of FIG. 9 to convert the circuit into the configuration shown in FIG. 7.

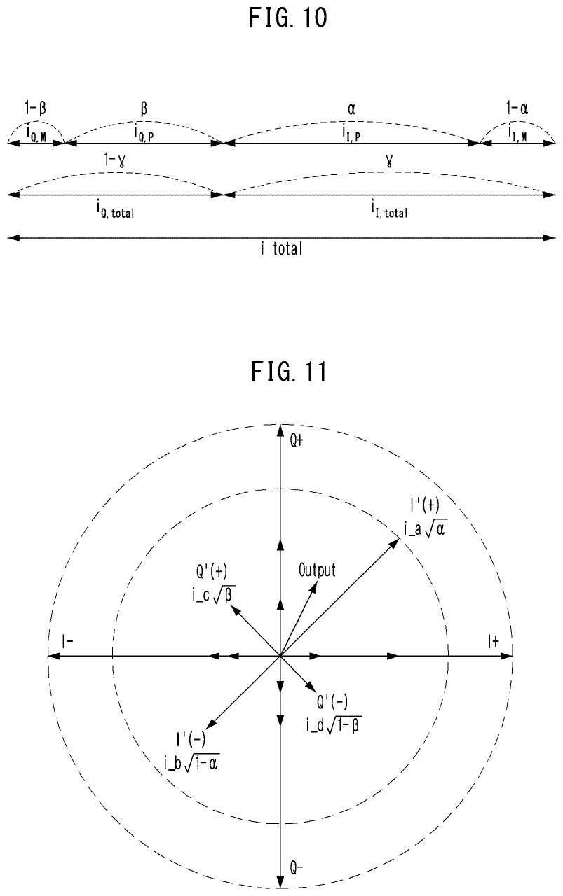

FIGS. 10 and 11 are diagrams for explaining operations of the circuit diagram shown in FIG. 9.

As shown in FIG. 10, assuming that the total sum of current is fixed, the ratio between a current i_{I,total} for controlling the I-axis and a current i_{Q,total} for controlling the Q-axis is controlled to satisfy the following Equation 1.

$${i}_{I , total} : {i}_{Q , total} = γ : 1 - γ \qquad [ Equation 1 ]$$

In addition, among the current i_{I,total} for controlling the I-axis, it is assumed that the ratio between a current i_{I,P} for controlling the positive direction (I+) and a current i_{I,M} for controlling the negative direction (I−) is controlled to satisfy the following Equation 2.

$${i}_{I , P} : {i}_{I , M} = α : 1 - α \qquad [ Equation 2 ]$$

In addition, among the current i_{Q,total} for controlling the Q-axis, it is assumed that the ratio between a current i_{Q,P} for controlling the positive direction (Q+) and a current i_{Q,M} for controlling the negative direction (Q−) is controlled to satisfy the following Equation 3.

$${i}_{Q , P} : {i}_{Q , M} = β : 1 - β \qquad [ Equation 3 ]$$

In this case, as shown in FIG. 11, the reference vector is changed. That is, while the reference axes of I+, I−, Q+, and Q− are used during the forward operation, in the reverse operation the reference vector is changed to I′(+), I′(−), Q′(+), and Q′(−).

At this time, the following relationships are satisfied:

$${I}^{′} ( + ) = I + + Q + , {I}^{′} ( - ) = I - + Q - , {Q}^{′} ( + ) = I - + Q + , and {Q}^{′} ( - ) = I + + Q - .$$

The simulation results of the bidirectional variable gain phase shifter are shown in Table 1 below.

TABLE 1

| | NF(Phase | NF(with 3 dB NF, |
|---|---|---|
| Operation mode | shifter only) | 15 dB LNA) |
| Forward direction(FW) | 8.139 dB | 3.364 dB |
| Reverse direction(BW) | 6.398 dB | 3.116 dB |

In [Table 1], noise figure (NF) values in the forward and reverse directions are shown. The noise figure is expressed as shown in the following Equation 4.

$$NF ( dB ) = 10 \cdot {log}_{10} ( \frac{S N {R}_{in}}{S N {R}_{out}} ) \qquad [ Equation 4 ]$$

That is, when the NF value is 0 dB, it represents an ideal circuit, indicating that no additional noise is present, and when it is greater than 0 dB, it means that the output signal contains more noise than the input signal. In typical circuits, the value appears as 0 dB or higher. As a result of simulation, it can be seen that in the forward direction, the NF value is 8.139 dB, which is slightly higher than the NF value of 3.364 dB in the reverse direction. This can be attributed to accumulated loss as the signal passes through the I/Q generator (3 dB loss), the phase shifter, and the output path. In other words, in the reverse direction, the path is simpler, resulting in less loss. As such, in the bidirectional variable gain phase shifter according to the exemplary embodiments of the present disclosure, even during the reverse operation, since the signal passes through the second circuit operating as a variable gain amplifier without passing through the I/Q generator having large insertion loss, and vector synthesis subsequently occurs in the first circuit (I/Q generator) operating as a vector combiner, an advantage is achieved in terms of noise figure.

Furthermore, it can be confirmed that when combined with a low noise amplifier (LNA) having a 3 dB NF and 15 dB gain, the overall NF is further reduced.

As described above, according to the bidirectional variable gain phase shifter of the exemplary embodiments of the present disclosure, even during the reverse operation, since the currents flowing through the four second quadrature signal terminals remain identical, stable vector synthesis is achievable.

In addition, by sharing a DAC and a passive network in both forward and reverse operations, circuit complexity can be significantly reduced and the chip area can be minimized.

Furthermore, in the reverse operation, since the signal passes through the second circuit operating as a variable gain amplifier without passing through the I/Q generator having large loss, and vector synthesis subsequently occurs in the first circuit (I/Q generator) operating as a vector combiner, an advantage is obtained in terms of noise figure.

The operation of the method according to exemplary embodiments of the present disclosure may be implemented as a program or code readable by a computer and stored in a computer-readable recording medium. The computer-readable recording medium includes all types of recording devices in which information readable by a computer system is stored. The computer-readable recording medium may also store and execute a program or code readable by a computer in a distributed manner over a network-connected computer system.

The computer-readable recording medium may include hardware devices specially configured to store and execute program instructions, such as read-only memory (ROM), random access memory (RAM), or flash memory. The program instructions may include not only machine code generated by a compiler but also high-level language code executable by a computer using an interpreter or the like.

Although certain aspects of the present disclosure have been described in the context of an apparatus, such descriptions may also correspond to explanations in the context of a method, where each block or element corresponds to a method step or feature thereof. Likewise, aspects described in the context of a method may also correspond to blocks, elements, or features of a corresponding apparatus. Some or all of the method steps may be performed by, or using, hardware devices such as a microprocessor, a programmable computer, or an electronic circuit. In some embodiments, at least one of the most significant method steps may be performed by such a device.

In certain embodiments, a programmable logic device, such as a field-programmable gate array (FPGA), may be used to perform part or all of the functions of the methods described herein. In some embodiments, the field-programmable gate array may operate in conjunction with a microprocessor to execute one of the methods described herein. Generally, it is desirable that the methods be performed by some type of hardware device.

The description of the disclosure is merely exemplary in nature and, thus, variations that do not depart from the substance of the disclosure are intended to be within the scope of the disclosure. Such variations are not to be regarded as a departure from the spirit and scope of the disclosure. Thus, it will be understood by those of ordinary skill in the art that various changes in form and details may be made without departing from the spirit and scope as defined by the following claims.

What is claimed is:

1. A bidirectional variable gain phase shifter comprising:
a first circuit including a pair of first differential signal terminals that receive or output differential signals and four first quadrature signal terminals that receive or output quadrature signals, the first circuit being configured to operate as an I/Q generator in a first direction and to operate as a vector combiner in a second direction opposite to the first direction;
a second circuit including four second quadrature signal terminals respectively connected to the four first quadrature signal terminals and a pair of second differential signal terminals, the second circuit being configured to operate as a vector combiner in the first direction and to operate as a variable gain differential amplifier in the second direction; and
a control circuit configured to control the second circuit through first, second, third, and fourth bias current sources,
wherein the first direction is from the first circuit toward the second circuit, and the second direction is from the second circuit toward the first circuit,
wherein, during a forward operation, a first DC bias currents flowing through the two second differential signal terminals are controlled to be substantially equal, and during a reverse operation, a second DC bias currents flowing through the four second quadrature signal terminals are controlled to be substantially equal.

2. The bidirectional variable gain phase shifter according to claim 1, wherein the second circuit comprises a plurality of transistors, and
the four second quadrature signal terminals correspond to output terminals of the plurality of transistors.

3. The bidirectional variable gain phase shifter according to claim 1, wherein, during the forward operation, a sum of DC bias currents flowing through the second differential signal terminals during the forward operation is maintained to be substantially equal to a sum of DC bias currents flowing through the second quadrature signal terminals during the reverse operation.

4. The bidirectional variable gain phase shifter according to claim 1, wherein the second circuit is configured such that a gain of each path varies according to phase information of signals input or output through the four second quadrature signal terminals.

5. The bidirectional variable gain phase shifter according to claim 1, wherein the second circuit comprises:
a first differential amplification circuit group including the four second quadrature signal terminals and the two second differential signal terminals; and
a second differential amplification circuit group sharing the second quadrature signal terminals and the second differential signal terminals of the first differential amplification circuit group.

6. The bidirectional variable gain phase shifter according to claim 5, wherein the first differential amplification circuit group and the second differential amplification circuit group output first and second differential signals generated based on signals input through the first quadrature signal terminals through mutually opposite second differential signal terminals.

7. The bidirectional variable gain phase shifter according to claim 5, wherein the control circuit provides bias currents respectively to the first differential amplification circuit group and the second differential amplification circuit group and is configured to maintain a total sum of the bias currents constant.

8. The bidirectional variable gain phase shifter according to claim 5, wherein the first differential amplification circuit group is controlled through the first and second bias current sources, and
the second differential amplification circuit group is controlled through the third and fourth bias current sources.

9. The bidirectional variable gain phase shifter according to claim 8, wherein the control circuit includes a digital-to-analog converter (DAC), and
the first, second, third, and fourth bias current sources are set according to output values of the DAC.

10. The bidirectional variable gain phase shifter according to claim 1, wherein, during the forward operation, the first quadrature signal terminals respectively output a first phase signal (I+), a second phase signal (I−), a third phase signal (Q+), and a fourth phase signal (Q−),
and during the reverse operation, the second quadrature signal terminals respectively output a fifth phase signal (I′(+)), a sixth phase signal (I′(−)), a seventh phase signal (Q′(+)), and an eighth phase signal (Q′(−)),
wherein phase-combined signals satisfy
$${I}^{′} ( + ) = I + + Q + ,$$
$${I}^{′} ( - ) = I - + Q - ,$$
$${Q}^{′} ( + ) = I - + Q + ,$$
$${Q}^{′} ( - ) = I + + Q - .$$

11. The bidirectional variable gain phase shifter according to claim 1, further comprising a first transmission line transformer connected to the first differential signal terminals.

12. The bidirectional variable gain phase shifter according to claim 1, further comprising a second transmission line transformer connected to the second differential signal terminals.
